(19) United States
(12) Patent Application Publication
(10) Pub. No.: US 2023/0315027 A1
(43) Pub. Date: Oct. 5, 2023

(54) MOTION CONTROL USING AN ARTIFICIAL NEURAL NETWORK

(71) Applicant: ASML NETHERLANDS B.V., Veldhoven (NL)

(72) Inventors: Koos VAN BERKEL, Waalre (NL); Joost Johan BOLDER, Waalre (NL); Stijn BOSMA, Rotterdam (NL)

(73) Assignee: ASML NETHERLANDS B.V., Veldhoven (NL)

(21) Appl. No.: 18/013,154

(22) PCT Filed: Jun. 17, 2021
(86) PCT No.: PCT/EP2021/066479

§ 371 Date: Dec. 27, 2022

Related U.S. Application Data
(60) Provisional application No. 63/049,719, filed on Jul. 9, 2020.

(51) Int. Cl. G05B 13/02; G06N 3/084; G03F 7/00

(52) U.S. Cl. CPC G05B 13/027; G03F 7/706841; G06N 3/084

(57) ABSTRACT

Variable setpoints and/or other factors may limit iterative learning control for moving components of an apparatus. The present disclosure describes a processor configured to control movement of a component of an apparatus with at least one prescribed movement. The processor is configured to receive a control input such as and/or including a variable setpoint. The control input indicates the at least one prescribed movement for the component. The processor is configured to determine, with a trained artificial neural network, based on the control input, a feedforward output for the component. The artificial neural network is pretrained with a training data set such that the artificial neural network determines the output regardless of whether or not the control input falls outside the training data set. The processor controls the component based on at least the output.

### CROSS-REFERENCE TO RELATED APPLICATION

The application claims priority of U.S. application 63/049,719 which was filed on Jul. 9, 2020 and which is incorporated herein in its entirety by reference.

### FIELD

The present disclosure relates to an apparatus, a method for controlling a component of an apparatus, and a non-transitory computer readable medium.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced, while the amount of functional elements, such as transistors, per device has been steadily increasing over decades, following a trend commonly referred to as ‘Moore's law’. To keep up with Moore's law the semiconductor industry is chasing technologies that enable it to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm, and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such a process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance.

To overcome these difficulties, sophisticated fine-tuning steps may be applied to the lithographic projection apparatus and/or design layout. These include, for example, but are not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low-k₁.

Hence, in lithographic processes, it is desirable to make frequent measurements of the structures created, e.g., for process control and verification. Tools to make such measurement are typically called metrology tools or inspection tools. Different types of metrology tools for making such measurements are known, including scanning electron microscopes or various forms of scatterometer metrology tools. Scatterometers are versatile instruments which allow measurements of the parameters of a lithographic process by having a sensor in the pupil or a conjugate plane with the pupil of the objective of the scatterometer, measurements usually referred as pupil based measurements, or by having the sensor in the image plane or a plane conjugate with the image plane, in which case the measurements are usually referred as image or field based measurements. Such scatterometers and the associated measurement techniques are further described in patent applications US2010/0328655, US2011/102753A1, US2012/0044470A, US2011/0249244, US2011/0026032 or EP1,628,164A, incorporated herein by reference in their entirety. Aforementioned scatterometers may measure gratings using light from soft x-ray and visible to near-IR wavelength range.

### SUMMARY

Successful Iterative Learning Control (ILC) of the motion of a component of an apparatus depends on a repetitive motion control setpoint for the component, repetitive disturbance forces, time variance of the system under control, and/or other factors. Disturbance forces may be forces that result from the movement of various components of an apparatus, the types of components used in an apparatus, the location of an apparatus, component wear, and/or other similar factors. A motion control setpoint may prescribe motion of a component of an apparatus. In semiconductor manufacturing and/or in other applications, setpoints and disturbance forces are often not repetitive. This can cause inaccuracies in the movement of a component of a semiconductor manufacturing apparatus, for example, even when controlled by an ILC system.

As such, it is an object of the present invention to provide systems and methods configured to more accurately control the motion of apparatus components when motion setpoints for the components and/or disturbance forces are not repetitive.

In contrast to prior systems, the present system is configured to control movement of a component of an apparatus based on output from a trained machine learning model. The machine learning model may be an artificial neural network, for example. The system is configured to receive a control input such as a variable motion setpoint. The system is configured to determine, with the trained machine learning model, based on the control input, a control output for the component. The machine learning model is trained with training data such that the machine learning model determines the control output regardless of whether or not the control input falls outside the training data. The system then controls the component based on at least the control output. Among other advantages, controlling movement of a component based on a control output from a trained machine learning model enhances component movement accuracy (e.g., the component better follows the prescribed movements in the motion setpoint) compared to prior systems. Conveniently, these features may be added to an existing controller.

Considering at least the above, according to an embodiment of the invention, there is provided an apparatus comprising: a component configured to move with at least one prescribed movement; and a processor configured by machine readable instructions. The processor is configured to receive a control input. The control input indicates the at least one prescribed movement for the component. The processor is configured to determine, with an artificial neural network, based on the control input, a control output for the component. The artificial neural network is trained with training data such that the artificial neural network determines the control output regardless of whether or not the control input falls outside the training data. The processor is configured to control the component based on at least the control output.

In some embodiments, the artificial neural network is pretrained with the training data. Training may be performed off-line, online, or off-line and online in combination. The training data may comprise a plurality of benchmark training control input and corresponding training control output pairs. In some embodiments, the training control inputs comprise a plurality of changing target parameters for the component. In some embodiments, the training control outputs comprise a plurality of known forces, torques, currents, and/or voltages for the component that correspond to the plurality of changing target parameters. The training may generate one or more coefficients for the artificial neural network.

In some embodiments, the control input (1) is prefiltered, and/or (2) comprises a scanning and/or stepping motion setpoint. In some embodiments, the control input comprises a digital signal indicating one or more of a position, a higher order time derivative of the position, a velocity, or an acceleration of the component over time. In some embodiments the control input comprises a digital signal indicating a position and one or more of a higher order time derivative of the position, for example a velocity, or an acceleration of the component over time. In some embodiments, the motion setpoint comprises a changing target parameter for the component.

In some embodiments, the apparatus comprises a semiconductor lithography apparatus, an optical metrology inspection tool, an e-beam inspection tool, and/or other systems.

In some embodiments, the component comprises a reticle stage, a wafer stage, a mirror, a lens element, and/or other components configured to move into and/or out of one or more positions for photolithography.

In some embodiments, the control output comprises one or more of forces, torques, currents, voltages, or charges used to control movement of the component.

According to another embodiment of the invention, there is provided a method for controlling a component of an apparatus. The method comprises receiving a control input. The control input indicates at least one prescribed movement of the component. The method comprises determining, with a trained artificial neural network, based on the control input, a control output for the component. The artificial neural network is trained with training data such that the artificial neural network determines the control output regardless of whether or not the control input falls outside the training data. The method comprises controlling the component based on at least the control output.

In some embodiments, the artificial neural network is pretrained with the training data. The training may be performed off-line, online, or off-line and online in combination. The training data may comprise a plurality of benchmark training control input and corresponding training control output pairs. Training control inputs may comprise a plurality of changing target parameters for the component. Training control outputs may comprise a plurality of known forces, torques, currents, and/or voltages for the component that correspond to the plurality of changing target parameters. The training may generate one or more coefficients for the artificial neural network.

In some embodiments, the control input (1) is prefiltered, and/or (2) comprises a stepping and/or a scanning motion setpoint. In some embodiments, the control input comprises a digital signal indicating one or more of a position, a higher order time derivative of the position, a velocity, or an acceleration of the component over time. In some embodiments, the control input comprises a digital signal indicating a position and one or more of a higher order time derivative of the position, for example a velocity, or an acceleration of the component over time. In some embodiments, the motion setpoint comprises a changing target parameter for the component.

In some embodiments, the apparatus comprises a semiconductor lithography apparatus, an optical metrology inspection tool, an e-beam inspection tool, and/or other systems.

In some embodiments, the component comprises a reticle stage, a wafer stage, a mirror, a lens element, and/or other components configured to move into and/or out of one or more positions for photolithography.

In some embodiments, the control output comprises one or more of forces, torques, currents, voltages, or charges used to control movement of the component.

According to another embodiment of the invention, there is provided a non-transitory computer readable medium having instructions thereon, the instructions when executed by a computer implementing the process of any of the embodiments described above.

According to another embodiment of the invention, there is provided a non-transitory computer readable medium having instructions thereon. The instructions, when executed by a computer, cause the computer to receive a control input, the control input indicating at least one prescribed movement of a component of an apparatus; determine, with a trained artificial neural network, based on the control input, a control output for the component, wherein the artificial neural network is trained with training data such that the artificial neural network determines the control output regardless of whether or not the control input falls outside the training data; and control the component based on at least the control output.

In some embodiments, the artificial neural network is pretrained with the training data. In some embodiments, the training is performed off-line, online, or off-line and online in combination. The training data may comprise a plurality of benchmark training control input and corresponding training control output pairs. Training control inputs may comprise a plurality of changing target parameters for the component. Training control outputs may comprise a plurality of known forces, torques, currents, and/or voltages for the component that correspond to the plurality of changing target parameters. The training may generate one or more coefficients for the artificial neural network.

In some embodiments, the control input (1) is prefiltered, and/or (2) comprises a stepping and/or a scanning motion setpoint. In some embodiments, the control input comprises a digital signal indicating one or more of a position, a higher order time derivative, a velocity, or an acceleration of the component over time. In some embodiments, the control input comprises a digital signal indicating a position and one or more of a higher order time derivative of the position, for example a velocity, or an acceleration of the component over time. In some embodiments, the setpoint comprises a changing target parameter for the component.

In some embodiments, the apparatus comprises a semiconductor lithography apparatus, an optical metrology inspection tool, an e-beam inspection tool, and/or other systems.

In some embodiments, the component comprises a reticle stage, a wafer stage, a mirror, a lens element, and/or other components configured to move into and/or out of one or more positions for photolithography.

In some embodiments, the control output comprises one or more of forces, torques, currents, voltages, or charges used to control movement of the component.

According to another embodiment of the invention, there is provided a non-transitory computer readable medium having instructions thereon, the instructions when executed by a computer causing the computer to train an artificial neural network with training data. The training data comprises a plurality of benchmark training control input and corresponding training control output pairs. The trained artificial neural network is configured to determine, based on a control input, a control output for a component of an apparatus, wherein: the artificial neural network is trained with training data such that the artificial neural network determines the control output regardless of whether or not the control input falls outside the training data; the control input indicating at least one prescribed movement of the component. The apparatus is configured to be controlled based on at least control output.

In some embodiments, the training is off-line, online, or off-line and online in combination. In some embodiments, training control inputs comprise a plurality of changing target parameters for the component. Training control outputs may comprise a plurality of known forces, torques, currents, and/or voltages for the component that correspond to the plurality of changing target parameters. The training may generate one or more coefficients for the artificial neural network.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a detailed view of a part of the lithographic apparatus of FIG. 1;

FIG. 3 schematically depicts a position control system;

FIG. 4 schematically depicts a schematic overview of a lithographic cell;

FIG. 5 schematically depicts a schematic representation of holistic lithography, representing a cooperation between three key technologies to optimize semiconductor manufacturing;

FIG. 6 schematically depicts a position control system with an iterative learning control (ILC) module;

FIG. 7 illustrates examples of two motion setpoints that result in different ILC-learned forces and moments;

FIG. 8 illustrates an example method for controlling a moving component of an apparatus;

FIG. 9 illustrates an example embodiment of the present system including the artificial neural network;

FIG. 10 is a block diagram of an example computer system.

### DETAILED DESCRIPTION

Iterative Learning Control (ILC) is a control technique that iteratively learns a feedforward control signal by converting a measured control error for an iteration “i” into a corrected feedforward control signal for iteration “i+1” when controlling motion of one or more components of an apparatus. This technique has been demonstrated in many motion control systems for components including wafer stages, for example, and typically reduces control errors by an order of magnitude or more with respect to other feedforward control systems.

However, as described above, successful ILC depends on a repetitive setpoint, repetitive disturbance forces, and/or other factors. Disturbance forces may be forces that result from the movement of various components of an apparatus, the types of components used in an apparatus, the location of an apparatus, component wear, and/or other similar factors. For example, disturbance forces may be related to motor commutation, a cable slab, system drift, etc. A setpoint may describe prescribed motion of a component of an apparatus. The motion setpoint may prescribe a position, velocity, acceleration, and/or other parameters (e.g., higher order time derivatives of such parameters, etc.) of the motion of the component over time. Successful ILC may depend on a repetitive setpoint trajectory for a given component including, for example, fixed length movements, fixed movement patterns, fixed movement velocities, fixed accelerations, repetitive jerking and/or snapping motions by a component, etc.

In semiconductor manufacturing and/or in other applications, setpoints and disturbance forces are often not repetitive. In semiconductor manufacturing, for example, setpoints may be varied for several reasons such as supporting different field sizes; real-time or near real-time changes for overlay corrections to correct for wafer heating, reticle heating, and/or mirror/lens heating; and/or for other reasons. The number of possible setpoint and/or disturbance force variations is theoretically infinite. In practice, the number of possible setpoint and/or disturbance force variations is too large to calibrate a motion control system (e.g., learn ILC feedforward signals) for individually. For example, an attempt at such calibration would require extensive use of an apparatus (e.g., a scanner in a lithography context) for calibration, and severely limit the availability of an apparatus for manufacturing purposes.

In contrast to prior systems, the present system is configured to control movement of a component of an apparatus based on output from a trained machine learning model. The machine learning model may be an artificial neural network, for example. The system is configured to receive a control input such as and/or including a variable motion setpoint. The system is configured to determine, with the artificial neural network, based on the control input, a control output for the component. The control output may be a feedforward signal, for example. The artificial neural network is trained with training data such that the artificial neural network determines the control output regardless of whether or not the control input falls outside the training data. The system then controls motion of the component based on at least the control output.

Among other advantages, controlling movement of a component based on a control output from a trained artificial neural network enhances component movement accuracy (e.g., the component better follows the prescribed movements in the motion setpoint) compared to prior systems. In semiconductor manufacturing, this may result in enhanced device dimension accuracy, higher yield, reduced process set up time, faster throughput, more accurate overlay and/or other process control measurements, and/or have other effects.

By way of a brief introduction, in the present document, motion control using a machine learning model is described in the context of integrated circuit and/or semiconductor manufacturing. One of ordinary skill in the art may apply principles of motion control using a machine learning model in other operations where precise control of one or more moving components of an apparatus is desired.

Given the present context, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm). The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

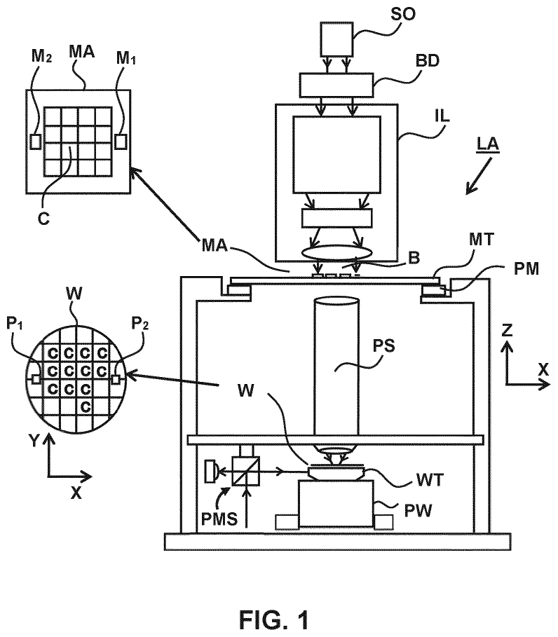

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axis is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

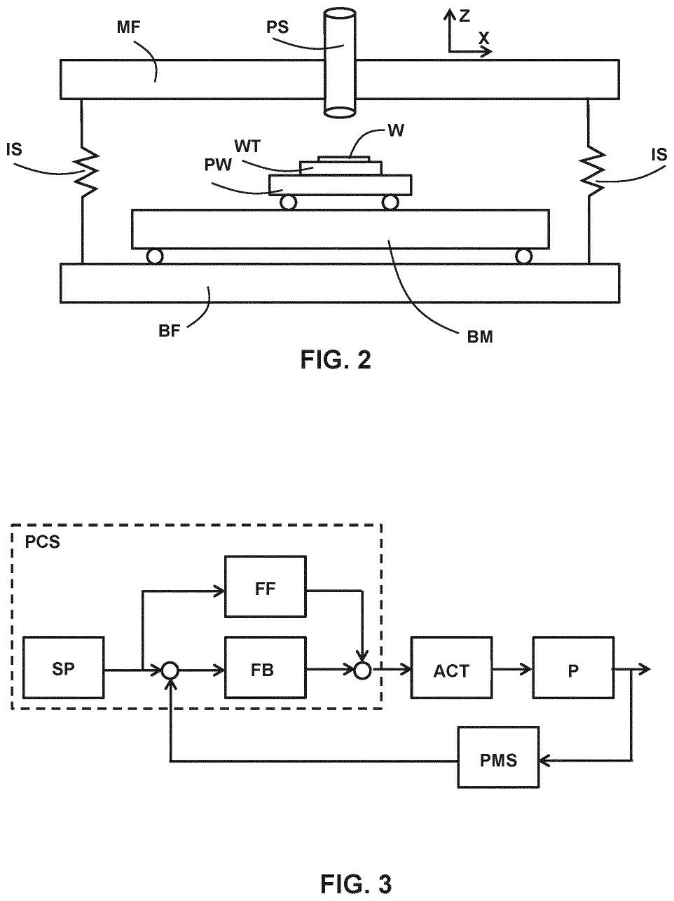

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The lithographic apparatus LA may comprise a position control system PCS as schematically depicted in FIG. 3. The position control system PCS comprises a setpoint generator SP, a feedforward controller FF and a feedback controller FB. The position control system PCS provides a drive signal to the actuator ACT. The actuator ACT may be the actuator of the first positioner PM or the second positioner PW, and/or other moving components of the lithographic apparatus LA. For example, the actuator ACT may drive the plant P, which may comprise the substrate support WT or the mask support MT. An output of the plant P is a position quantity such as position or velocity or acceleration or another higher order time derivative of the position. The position quantity is measured with the position measurement system PMS. The position measurement system PMS generates a signal, which is a position signal representative of the position quantity of the plant P. The setpoint generator SP generates a signal, which is a reference signal representative of a desired position quantity of the plant P. For example, the reference signal represents a desired trajectory of the substrate support WT. A difference between the reference signal and the position signal forms an input for the feedback controller FB. Based on the input, the feedback controller FB provides at least part of the drive signal for the actuator ACT. The reference signal may form an input for the feedforward controller FF. Based on the input, the feedforward controller FF provides at least part of the drive signal for the actuator ACT. The feedforward FF may make use of information about dynamical characteristics of the plant P, such as mass, stiffness, resonance modes and eigenfrequencies. Additional details of the system shown in FIG. 3 are described below.

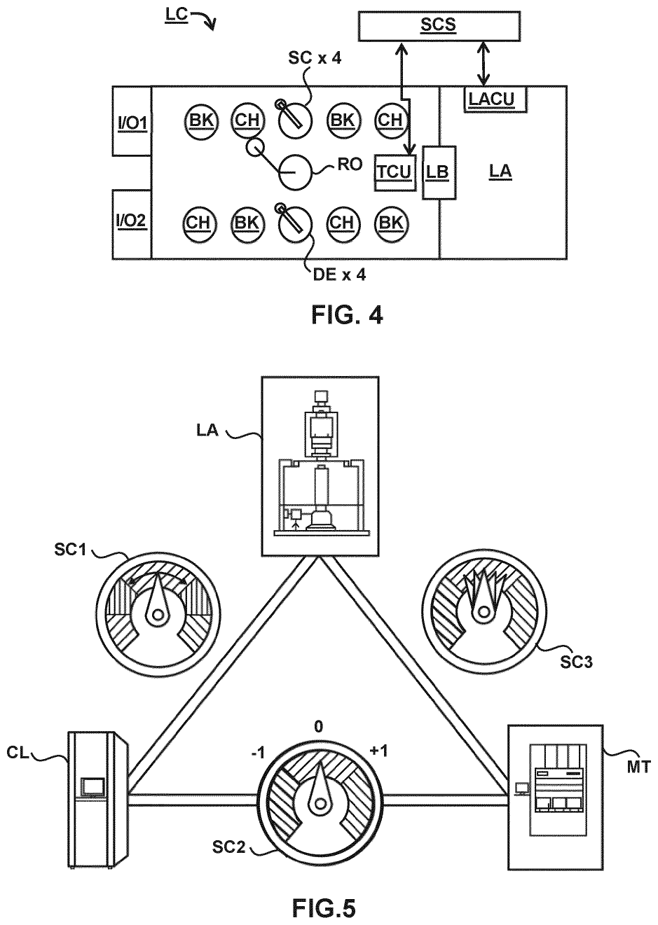

As shown in FIG. 4 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 5. One of these systems is the lithographic apparatus LA which is (virtually) connected to a metrology tool MT (a second system) and to a computer system CL (a third system). The key of such a “holistic” environment is to optimize the cooperation between these three systems to enhance the overall process window and to provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 5 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 5 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

As mentioned above by reference to the FIGS. 1-5, the lithographic apparatus, the metrology tool and/or lithocell typically include a plurality of stage systems used to position a specimen, substrate, mask or sensor arrangement relative to a reference or another component. Examples thereof are the mask support MT and first positioner PM, the substrate support WT and the second positioner PW, the measurement stage arranged to hold a sensor and/or a cleaning device, and the stage used in the inspection tool MT where a substrate W is positioned relative to e.g. a scanning electron microscope or some kind of scatterometer. These apparatuses may include several other moving components such as a reticle stage, a wafer stage, mirrors, lens elements, light sources (e.g., a drive laser, an EUV source, etc.), a reticle masking stage, a wafer top cooler, wafer and reticle handlers, vibration isolation systems, stage torque compensators, software and/or hardware modules that control and/or include such components, and/or other components. These examples are not intended to be limiting.

As described above, the present system is configured to control movement of a component (e.g., such as one or more of those described in the prior paragraph(s)) of an apparatus based on output from a trained machine learning model. The machine learning model may be an artificial neural network, for example. The system is configured to receive a control input such as and/or including a variable motion setpoint. The system is configured to determine, with the trained machine learning model, based on the control input, a control output (e.g., a feedforward signal and/or individual components of a feedforward signal) for the component. The control output may comprise forces, torques, currents, charges, voltages, and/or other information for a moving component that correspond to a given input variable motion setpoint. The machine learning model is trained with training data such that the machine learning model determines the control output regardless of whether or not the control input falls outside the training data. The system then controls the component based on at least the control output.

For example, the present machine learning model (e.g., one or more artificial neural networks) is effective in motion setpoint interpolation, and facilitates extrapolation beyond prior motion setpoints, with a limited and acceptable training (e.g., calibration) need. In other words, if separate control outputs for corresponding control inputs are known and used to train the machine learning model, the machine learning model can determine new control outputs for corresponding control inputs that lie somewhere between the known control inputs (e.g., prior motion setpoints), or somewhere outside the known control inputs.

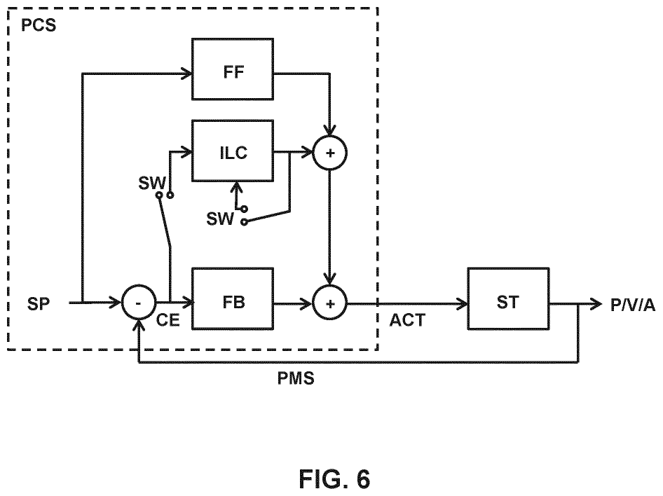

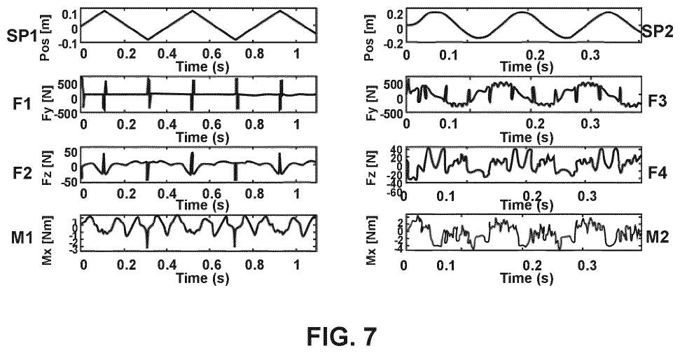

An overview of the present approach is as follows. ILC may be applied to a training set of motion setpoints (e.g., control inputs) for the movement of a stage in a lithography apparatus (as just one example) within a predefined setpoint space (e.g., for various lithography scan lengths, scan velocities, accelerations, etc.). Learned feedforward signals (forces, torques, currents, charges, voltages, and/or other information for the stage that correspond to a given variable motion setpoint) may be recorded and stored, along with their corresponding setpoints. In some embodiments, a system similar to and/or the same as the system shown in FIG. 6 may be used for these operations.

FIG. 6 is similar to FIG. 3, but with an added ILC module (shown as ILC in FIG. 6)). FIG. 6 also illustrates a control error CE, and a stage ST, in addition to the position control system PCS as schematically depicted in FIG. 3. As described above, the position control system PCS comprises a setpoint generator SP, a feedforward controller FF and a feedback controller FB. The position control system PCS provides a drive signal to the actuator ACT. The actuator ACT may actuate the stage ST such that the stage ST has a specific position quantity such as position or velocity or acceleration (P/V/A). The position quantity is measured with the position measurement system PMS. The position measurement system PMS generates a signal, which is a position signal representative of the position quantity of the stage ST. The setpoint generator SP generates a signal, which is a reference signal representative of a desired position quantity of the stage ST. For example, the reference signal represents a desired trajectory of the stage ST. A difference between the reference signal and the position signal (e.g., a control error CE) forms an input for the feedback controller FB. Based on the input, the feedback controller FB provides at least part of the drive signal for the actuator ACT. The reference signal may form an input for the feedforward controller FF. Based on the input, the feedforward controller FF provides at least part of the drive signal for the actuator ACT. The feedforward controller FF may make use of information about dynamical characteristics of the stage ST, such as mass, stiffness, resonance modes and eigenfrequencies. It should be noted that the switches SW indicate how the ILC module may be updated offline for a full scan-profile time trace (e.g., in the context of a lithography apparatus). The ILC module may be configured such that a feedforward signal is determined by minimizing (or optimizing) a prediction of the control error for the upcoming trial, where the feed forward signal is the free variable (which may be done in many different ways).

FIG. 7 illustrates how, in semiconductor manufacturing and/or in other applications, motion setpoints (e.g., control inputs as described herein) are often not repetitive. In semiconductor manufacturing, for example, setpoints may be varied for several reasons such as supporting different field sizes; real-time or near real-time changes for overlay corrections to correct for wafer heating, reticle heating, and/or mirror/lens heating; and/or for other reasons. The number of possible setpoint and/or disturbance force variations is theoretically infinite. FIG. 7 illustrates examples of two motion setpoints resulting in different ILC-learned forces and moments (e.g., possible components of a feedforward signal). These and other setpoints and corresponding learned forces and moments may be included in the recorded and stored information described above (which are eventually used to train the artificial neural network as described below).

Two different setpoints SP1 and SP2 are shown in FIG. 7. SP1 and SP2 each comprise prescribed positions over time for a moving component of an apparatus. FIG. 7 also illustrates ILC-learned forces F1 (Fy), F2 (Fz), F3 (Fy), F4 (Fz), and moments M1 (Mx), M2 (Mx) shown below each setpoint. The compensation signals (Fy, Fz, Mx) required to follow the reference (y in top row, z=0, Rx=0) are very different when the setpoint is modified (SP1 vs SP2).

Returning to the overview of the present approach, the artificial neural network may be trained with the recorded and stored motion setpoints and corresponding feedforward signals to reproduce the feedforward signals given a specific setpoint. For example, input to the artificial neural network may be a prescribed position, velocity, acceleration, jerk, and/or other parameters as a function of time. The artificial neural network may output feedforward forces, torques, and other parameters that mimic those learned with ILC. The artificial neural network may be implemented (e.g., as a feedforward add-on replacing the ILC module in FIG. 6), and the artificial neural network may generate new feedforward signals for new motion control setpoints (prescribed movements of a stage and/or other components of an apparatus) in real-time and/or near real time (e.g., at a frequency >10 kHz).

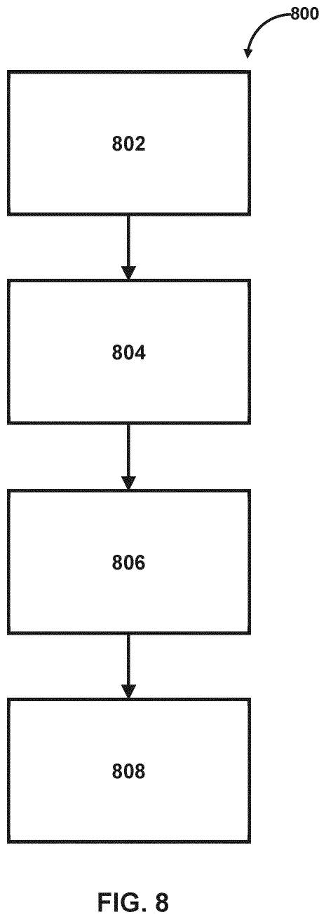

FIG. 8 illustrates an example method 800 for controlling a moving component of an apparatus. Method 800 may be associated with a moving component of a lithography apparatus, optical and/or e-beam inspection tools, an atomic-force microscopy (AFM) based inspection tool, and/or other systems. As described above, the component may be and/or include a reticle stage, a wafer stage, mirrors, lens elements, light sources (e.g., a drive laser, an EUV source, etc.), a reticle masking stage, a wafer top cooler, wafer and reticle handlers, vibration isolation systems, stage torque compensators, software and/or hardware modules that include such components, and/or other components.

Method 800 comprises training 802 an artificial neural network; receiving 804 a control input for the moving component; determining 806, with the artificial neural network, a control output; and controlling 808 the moving component of the apparatus based at least on the control output; and/or other operations. In some embodiments, method 800 is performed for (or as part of) a semiconductor manufacturing process, for example. In some embodiments, the component is configured to be moved into and/or out of one or more positions for lithography, inspection, etc.

The operations of method 800 presented below are intended to be illustrative. In some embodiments, method 800 may be accomplished with one or more additional operations not described, and/or without one or more of the operations discussed. For example, method 800 may not require training the artificial neural network (e.g., the artificial neural network may be pretrained). Additionally, the order in which the operations of method 800 are illustrated in FIG. 8 and described below is not intended to be limiting.

In some embodiments, one or more portions of method 800 may be implemented (e.g., by simulation, modeling, etc.) in one or more processing devices (e.g., one or more processors). The one or more processing devices may include one or more devices executing some or all of the operations of method 800 in response to instructions stored electronically on an electronic storage medium. The one or more processing devices may include one or more devices configured through hardware, firmware, and/or software to be specifically designed for execution of one or more of the operations of method 800, for example.

As described above, method 800 comprises training 802 an artificial neural network. For example, the artificial neural network may have an input layer, an output layer, and one or more intermediate or hidden layers. In some embodiments, the one or more artificial neural networks may be and/or include deep neural networks (e.g., neural networks that have one or more intermediate or hidden layers between the input and output layers).

As an example, the one or more artificial neural networks may be based on a large collection of neural units (or artificial neurons). The one or more neural networks may loosely mimic the manner in which a biological brain works (e.g., via large clusters of biological neurons connected by axons). Each neural unit of an artificial neural network may be connected with many other neural units of the neural network. Such connections can be enforcing or inhibitory in their effect on the activation state of connected neural units. In some embodiments, each individual neural unit may have a summation function that combines the values of all its inputs together. In some embodiments, each connection (or the neural unit itself) may have a threshold function such that a signal must surpass the threshold before it is allowed to propagate to other neural units. These neural network systems may be self-learning and trained, rather than explicitly programmed, and can perform significantly better in certain areas of problem solving, as compared to traditional computer programs. In some embodiments, the one or more artificial neural networks may include multiple layers (e.g., where a signal path traverses from front layers to back layers). In some embodiments, back propagation techniques may be utilized by the artificial neural networks, where forward stimulation is used to reset weights and/or biases on the “front” neural units. In some embodiments, stimulation and inhibition for the one or more neural networks may be more free flowing, with connections interacting in a more chaotic and complex fashion. In some embodiments, the intermediate layers of the one or more artificial neural networks include one or more convolutional layers, one or more recurrent layers, and/or other layers. By way of a non-limiting example, an artificial neural network may have ten neurons distributed between an input layer, three hidden layers, and an output layer. Such an artificial neural network may have sufficient degrees of freedom to capture non-linearities in multiple dimensions and compute a feedforward signal at a sampling rate of >10 kHz on a typical computing system (e.g., a laptop). It should be noted that this can be much faster with dedicated code and hardware.

The one or more neural networks may be trained (i.e., whose parameters are determined) using a set of training data (e.g., as described herein). The training data may comprise a plurality of benchmark training control input and corresponding training control output pairs. The training data may include a set of training samples. Each sample may be a pair comprising an input object (often formatted as a vector, which may be called a feature vector) and a desired output value (also called the supervisory signal). A training algorithm analyzes the training data and adjusts the behavior of the artificial neural network by adjusting the parameters (e.g., weights, biases, etc., of one or more layers and/or other parameters) of the artificial neural network based on the training data. For example, given a set of N training samples of the form {(x₁, y₁), (x₂, y₂), . . . , (xN, yN)} such that x₁ is the feature vector of the i-th example and y₁ is its supervisory signal, a training algorithm seeks a neural network g:X→Y, where X is the input space and Y is the output space. A feature vector is an n-dimensional vector of numerical features that represent some object (e.g., a control input such as a motion setpoint, a control output such as a feedforward signal, etc.). The vector space associated with these vectors is often called the feature or latent space. After training, the neural network may be used for making predictions using new samples (e.g., different motion setpoints and/or other control inputs).

In some embodiments, training control inputs comprise a plurality of changing target parameters for the component. The changing target parameters may be described by a motion setpoint, for example. The changing target parameters may include a position, a higher order time derivative of the position, a velocity, an acceleration, and/or other parameters. In some embodiments, the training control inputs may comprise digital signals indicating one or more of the position, the higher order time derivative of the position, the velocity, or the acceleration of the component over time, for example. In some embodiments, training control inputs may comprise digital signal indicating a position and one or more of a higher order time derivative of the position, for example a velocity, or an acceleration of the component over time. In some embodiments, training control inputs may include disturbance forces (e.g., as described above) and/or other information.

Training control outputs may comprise known feedforward signals, for example. These may include a plurality of known forces, torques, currents, charges, voltages, and/or other information for the component that correspond to the plurality of motion setpoints (e.g., changing target parameters). Specific examples of benchmark training data may include control inputs and outputs comprising Iterative Learning Control data, Machine-In-Loop optimized feedforward signals, and/or other data, for example. The benchmark training data may include error data (e.g., data indicating a difference between a prescribed position/velocity/acceleration/etc. and an actual position/velocity/acceleration/etc. of the component), and/or other information.

The trained artificial neural network is configured to determine, based on a control input, a control output for the component. The artificial neural network is trained with the training data such that the artificial neural network determines the control output regardless of whether or not the control input falls outside the training data. This means that the artificial neural network can interpolate between know motion control setpoints and corresponding feedforward signals, and/or extrapolate beyond the known motion control setpoints and corresponding feedforward signals, for example.

In some embodiments, the training is off-line, online, or off-line and online in combination. Offline training may comprise a procedure that takes place separately from the component and/or the apparatus. This means that machine (apparatus) production (e.g., semiconductor manufacturing) does not need to be interrupted while training the artificial neural network. Online training comprises training with the machine (apparatus) inside the training loop. This would require production to be interrupted as the machine (apparatus) is required to perform training motions.

The training may generate one or more coefficients for the artificial neural network. The one or more coefficients may include layer and/or individual neuron weights and/or biases, for example, and/or other coefficients. These coefficients may change over time responsive to the model being retrained, manual adjustment by a user, and/or other operations.

It should be noted, that even though training the artificial neural network is described in the context of a single moving component of an apparatus, the artificial neural network is also trained to account for more than one moving component in one or more apparatuses, and/or interactive effects between one or more such components. For example, the interactive effects may include and/or cause the disturbance forces described herein.

Method 800 comprises receiving 804 a control input for the moving component. The control input indicates at least one prescribed movement of the component. The control input may be a motion setpoint for example. In some embodiments, the control input comprises a stepping and/or a scanning (e.g., for a lithography apparatus) motion setpoint. In some embodiments, the motion setpoint comprises a changing target parameter for the component. The changing target parameter may be a position, a higher order time derivative of the position, a velocity, an acceleration, and/or other parameters. In some embodiments, the control input comprises a digital signal indicating one or more of the position, the higher order time derivative of the position, the velocity, or the acceleration of the component over time, for example. In some embodiments, the control input comprises a digital signal indicating a position and one or more of a higher order time derivative of the position, for example a velocity, or an acceleration of the component over time. In some embodiments, a control input may be similar to and/or the same as SP1 and/or SP2 shown in FIG. 7. For example, the control input may prescribe different positions for a component (e.g., a reticle stage) over time. The control input may prescribe movement according to a triangle wave (SP1), a sine wave (SP2), and/or according to any other pattern. However, at least because the present system and method utilize an artificial neural network (which can interpolate and/or extrapolate based on its training), a control input need not be the same as any control input used for training. Advantageously, a control input may be a motion setpoint that lies within motion setpoints used for training (e.g., has parameters that are different than, but do not breach the extremes of a range of values for, corresponding parameters in motion setpoints used for training), and/or outside motion setpoints used for training (e.g., has parameters that do breach the extremes of the range of values for corresponding parameters in motion setpoints used for training).

In some embodiments, the control input is prefiltered. Filtering may include low-pass, high-pass, band-pass, and/or other filtering. Filtering may be performed to limit the frequency bandwidth over which the neural network is “active”, which may avoid amplifier saturation and/or other effects. As another example, nonlinear analytical functions such as trigonometric functions (sine, cosine) may be applied to make the relation between input and output of the neural network simpler (e.g., if one wants to know whether an effect is repetitive in frequency, this can shorten the training process).

Returning to FIG. 8, method 800 comprises determining 806, with the artificial neural network, a control output. The control output is determined with the trained artificial neural network based on the control input and/or other information. The control output may be and/or include a feedforward signal, for example. In some embodiments, as described above, the control output comprises forces, torques, currents, voltages, charges and/or other information used to control movement of the component.

In some embodiments, a control output may include forces, torques, currents, voltages, charges, and/or other information similar to and/or the same as F1-F4 and/or M1-M2 shown in FIG. 7. For example, the control output may convey different forces (e.g., F1 and F2 versus F3 and F4) and/or moments (M1 versus M2), etc., for a component (e.g., a reticle stage) over time, depending on the control input (e.g., the motion setpoint). Again, at least because the present system and method utilize an artificial neural network (which can interpolate and/or extrapolate based on its training), a control output need not be the same as any control output used for training. Advantageously, a control output may be a feedforward signal that lies within feedforward signals used for training, and/or outside feedforward signals used for training.

Returning to FIG. 8, method 800 comprises controlling 808 the moving component of the apparatus based at least on the control output. Controlling 808 the moving component may include generating a feedforward signal and/or other electronic signals. Controlling 808 the moving component may include transmitting the feedforward signal and/or other electronic signals to the moving component (and/or one or more actuators controlling the moving component) and/or overall apparatus that includes the component. The movement of the component may be controlled based on information in addition to the control output. For example, the movement of the component may be controlled based on feedback control information (e.g., see FB in FIG. 3 and/or FIG. 6), ordinary physics governing the movement of the component (e.g., see FF in FIG. 3 and/or FIG. 6), and/or other information. In an preferred embodiment all known and ordinary physics is accurately modelled and controlled via feedforward signal FF.

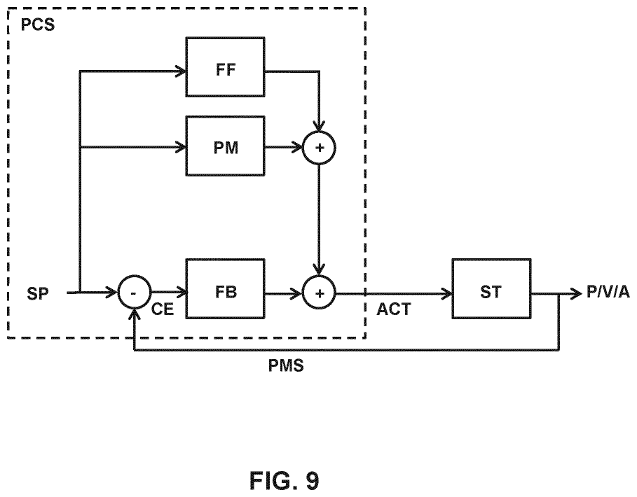

By way of a non-limiting example, FIG. 9 illustrates a possible embodiment of the present system including the artificial neural network PM. FIG. 9 illustrates how the present system can be considered as a data-based feedforward add on that focuses on the (often non-linear) residual, after the physics-based feedforward (such as mass- and snap-feedforward). This enables complementary implementation of machine learning model-based control with existing control methods already present. FIG. 9 illustrates how the artificial neural network PM may be added in a different configuration than that used for ILC, but nonetheless as a complimentary add on to the other system components. As described herein, and shown in FIG. 9, a processor (see FIG. 11 below) of the present system is configured to receive a control input such as and/or including a variable setpoint SP. The control input indicates the at least one prescribed movement for a component such as a stage ST. The processor is configured to determine, with an artificial neural network PM, based on the control input SP, a control output P/V/A for the component. The artificial neural network PM is trained with training data such that the artificial neural network PM determines the control output regardless of whether or not the control input falls SP outside the training data. The processor controls the component ST (via an actuator ACT) based on at least the control output. In the example shown in FIG. 9, the processor also controls the component ST based on feedback information (from a feedback controller) FB and information from a feedforward controller FF. This example is not intended to be limiting.

As described herein, the artificial neural network can determine the control output for the component regardless of whether or not the control input (e.g., a motion setpoint) falls outside the training data. Artificial neural networks are effective at interpolation and extrapolation. Motion setpoints (comprising various scan velocities, scan lengths, and scan accelerations for a lithography apparatus, for example) between the training data motion setpoints are interpolated by the artificial neural network accurately (>90% with respect to a before ILC case). With the present systems and methods, extrapolating (scan) accelerations for the motion setpoints (to produce extrapolated motion setpoints) still gives decent performance (e.g., accuracies at or above 75%).

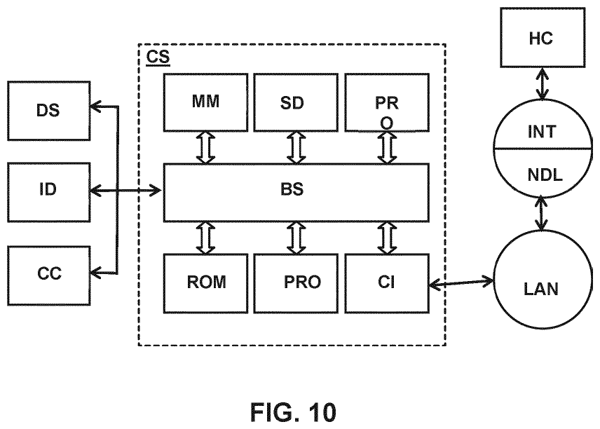

FIG. 10 is a block diagram of an example computer system CS, according to an embodiment. Computer system CS may assist in implementing the methods, flows, or the apparatus disclosed herein. Computer system CS includes a bus BS or other communication mechanism for communicating information, and a processor PRO (or multiple processors) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO, for example. Computer system CS includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. As described herein, a machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses.
1. An apparatus comprising:
   a component configured to move with at least one prescribed movement; and
   a processor configured by machine readable instructions to:
      receive a control input, the control input indicating the at least one prescribed movement for the component;
      determine, with a trained machine learning model, based on the control input, a control output for the component, wherein the machine learning model is trained with training data such that the machine learning model determines the control output regardless of whether or not the control input falls outside the training data; and
      control the component based on at least the control output.
2. The apparatus of clause 1, wherein the machine learning model is an artificial neural network.
3. The apparatus of any of clauses 1-2, wherein the control input (1) is prefiltered, and/or (2) comprises a scanning and/or stepping motion setpoint.
4. The apparatus of clause 3, wherein the motion setpoint comprises a changing target parameter for the component.
5. The apparatus of any of clauses 1-4, wherein the apparatus comprises a semiconductor lithography apparatus, an optical metrology inspection tool, or an e-beam inspection tool.
6. The apparatus of any of clauses 1-5, wherein the component comprises a reticle stage, a wafer stage, a mirror, or a lens element, configured to move into and/or out of one or more positions for photolithography.
7. The apparatus of any of clauses 1-6, wherein the control input comprises a digital signal indicating one or more of a position, a higher order time derivative of the position, a velocity, or an acceleration of the component over time.
8. The apparatus of any of clauses 1-6, wherein the control input comprises a digital signal indicating a position and one or more of a higher order time derivative of the position, for example a velocity, or an acceleration of the component over time.
9. The apparatus of any of clauses 1-8, wherein the control output comprises one or more of forces, torques, currents, voltages, or charges used to control movement of the component.
10. The apparatus of any of clauses 1-9, wherein the machine learning model is pretrained with the training data.
11. The apparatus of clause 10, wherein training is performed off-line, online, or off-line and online in combination.
12. The apparatus of clause 10 or 11, wherein the training data comprises a plurality of benchmark training control input and corresponding training control output pairs.
13. The apparatus of clause 12, wherein training control inputs comprise a plurality of changing target parameters for the component.
14. The apparatus of clause 13, wherein training control outputs comprise a plurality of known forces, torques, currents, and/or voltages for the component that correspond to the plurality of changing target parameters.
15. The apparatus of any of clauses 10-14, wherein the training generates one or more coefficients for the machine learning model.
16. A method for controlling a component of an apparatus, the method comprising:
   receiving a control input, the control input indicating at least one prescribed movement of the component;
   determining, with a trained machine learning model, based on the control input, a control output for the component, wherein the machine learning model is trained with training data such that the machine learning model determines the control output regardless of whether or not the control input falls outside the training data; and
   controlling the component based on at least the control output.
17. The method of clause 16, wherein the machine learning model is an artificial neural network.
18. The method of any of clauses 16-17, wherein the control input (1) is prefiltered, and/or (2) comprises a stepping and/or a scanning motion setpoint.
19. The method of clause 18, wherein the motion setpoint comprises a changing target parameter for the component.
20. The method of any of clauses 16-19, wherein the apparatus comprises a semiconductor lithography apparatus, an optical metrology inspection tool, or an e-beam inspection tool.
21. The method of any of clauses 16-20, wherein the component comprises a reticle stage, a wafer stage, a mirror, or a lens element, configured to move into and/or out of one or more positions for photolithography.
22. The method of any of clauses 16-21, wherein the control input comprise a digital signal indicating one or more of a position, a higher order time derivative of the position, a velocity, or an acceleration of the component over time.
23. The apparatus of any of clauses 16-21, wherein the control input comprises a digital signal indicating a position and one or more of a higher order time derivative of the position, for example a velocity, or an acceleration of the component over time.
24. The method of any of clauses 16-23, wherein the control output comprises one or more of forces, torques, currents, voltages, or charges used to control movement of the component.
25. The method of any of clauses 16-24, wherein the machine learning model is pretrained with the training data.
26. The method of clause 25, wherein training is performed off-line, online, or off-line and online in combination.
27. The method of clause 25 or 26, wherein the training data comprises a plurality of benchmark training control input and corresponding training control output pairs.
28. The method of clause 27, wherein training control inputs comprise a plurality of changing target parameters for the component.
29. The method of clause 28, wherein training control outputs comprise a plurality of known forces, torques, currents, and/or voltages for the component that correspond to the plurality of changing target parameters.
30. The method of any of clauses 25-29, wherein the training generates one or more coefficients for the machine learning model.
31. A non-transitory computer readable medium having instructions thereon, the instructions when executed by a computer implementing the process of any of clauses 16-30.
32. A non-transitory computer readable medium having instructions thereon, the instructions when executed by a computer causing the computer to:
   receive a control input, the control input indicating at least one prescribed movement of a component of an apparatus;
   determine, with a trained machine learning model, based on the control input, a control output for the component, wherein the machine learning model is trained with training data such that the machine learning model determines the control output regardless of whether or not the control input falls outside the training data; and
   control the component based on at least the control output.
33. The medium of clause 32, wherein the machine learning model is an artificial neural network.
34. The medium of any of clauses 32-33, wherein the control input (1) is prefiltered, and/or (2) comprises a stepping and/or a scanning motion setpoint.
35. The medium of clause 34, wherein the setpoint comprises a changing target parameter for the component.
36. The medium of any of clauses 32-35, wherein the apparatus comprises a semiconductor lithography apparatus, an optical metrology inspection tool, or an e-beam inspection tool.
37. The medium of any of clauses clause 32-36, wherein the component comprises a reticle stage, a wafer stage, a mirror, or a lens element, configured to move into and/or out of one or more positions for photolithography.
38. The medium of any of clauses 32-37, wherein the control input comprises a digital signal indicating one or more of a position, a higher order time derivative, a velocity, or an acceleration of the component over time.
39. The apparatus of any of clauses 32-37, wherein the control input comprises a digital signal indicating a position and one or more of a higher order time derivative of the position, for example a velocity, or an acceleration of the component over time.
40. The medium of any of clauses 32-39, wherein the control output comprises one or more of forces, torques, currents, voltages, or charges used to control movement of the component.
41. The medium of any of clauses 32-40, wherein the machine learning model is pretrained with the training data.
42. The medium of clause 41, wherein training is performed off-line, online, or off-line and online in combination.
43. The medium of clause 41 or 42, wherein the training data comprises a plurality of benchmark training control input and corresponding training control output pairs.
44. The medium of clause 43, wherein training control inputs comprise a plurality of changing target parameters for the component.
45. The medium of clause 43 or 44, wherein training control outputs comprise a plurality of known forces, torques, currents, and/or voltages for the component that correspond to the plurality of changing target parameters.
46. The medium of any of clauses 41-45, wherein the training generates one or more coefficients for the machine learning model.
47. A non-transitory computer readable medium having instructions thereon, the instructions when executed by a computer causing the computer to:
   train a machine learning model with training data, the training data comprising a plurality of benchmark training control input and corresponding training control output pairs;
   the trained machine learning model being configured to determine, based on a control input, a control output for a component of an apparatus, wherein:
      the machine learning model is trained with training data such that the machine learning model determines the control output regardless of whether or not the control input falls outside the training data;
      the control input indicates at least one prescribed movement of the component; and
      the apparatus is configured to be controlled based on at least control output.
48. The medium of clause 47, wherein training is off-line, online, or off-line and online in combination.
49. The medium of clause 47 or 48, wherein training control inputs comprise a plurality of changing target parameters for the component.
50. The medium of any of clauses 47-49, wherein training control outputs comprise a plurality of known forces, torques, currents, and/or voltages for the component that correspond to the plurality of changing target parameters.
51. The medium of any of clauses 47-50, wherein the training generates one or more coefficients for the machine learning model.

1. An apparatus comprising:
a component configured to move with at least one prescribed movement; and
a processor configured by machine readable instructions to:
receive a control input, the control input indicating the at least one prescribed movement for the component;
determine, with a trained artificial neural network, based on the control input, a feedforward output for the component, wherein the artificial neural network is pretrained with a training data set such that the artificial neural network determines the output regardless of whether or not the control input falls outside the training data set; and
control the component based on at least the output.

2. The apparatus of claim 1, wherein the control input (1) is pretiltered, and/or (2) comprises a scanning and/or stepping motion setpoint.

3. The apparatus of claim 2, wherein the control input comprises the scanning and/or stepping motion setpoint and the motion setpoint comprises a changing target parameter for the component.

4. The apparatus of claim 1, wherein the apparatus comprises a semiconductor lithography apparatus, an optical metrology inspection tool, or an e-beam inspection tool.

5. The apparatus of claim 1, wherein the component comprises a reticle stage, a wafer stage, a mirror, or a lens element, configured to move into and/or out of one or more positions for photolithography.

6. The apparatus of claim 1, wherein the control input comprises a digital signal indicating one or more selected from: a position, a higher order time derivative of the position, a velocity, or an acceleration of the component over time.

7. The apparatus of claim 1, wherein the control input comprises a digital signal indicating a position and one or more selected from: a higher order time derivative of the position or an acceleration of the component over time.

8.-9. (canceled)

10. The apparatus of claim 1, wherein training is performed off-line, online, or off-line and online in combination.

11. The apparatus of claim 1, wherein the training data comprises a plurality of benchmark training control input and corresponding training output pairs.

12. (canceled)

13. The apparatus of claim 11, wherein training outputs comprise a plurality of known forces, torques, currents, and/or voltages for the component that correspond to the plurality of changing target parameters.

14. The apparatus of claim 10, wherein the training generates one or more coefficients for the artificial neural network.

15. A method for controlling a component of an apparatus, the method comprising:
receiving a control input, the control input indicating at least one prescribed movement of the component;
determining, with a trained artificial neural network, based on the control input, a feedforward output for the component, wherein the artificial neural network is pretrained with a training data set such that the artificial neural network determines the output regardless of whether or not the control input falls outside the training data set; and
controlling the component based on at least the output.

16. The method of claim 15, wherein the control input (1) is prefiltered, and or (2) comprises a stepping and or a scanning motion setpoint.

17. The method of claim 16, wherein the control input comprises the scanning and/or stepping motion setpoint and wherein the motion setpoint comprises a changing target parameter for the component.

18. The method of claim 15, wherein the apparatus comprises a semiconductor lithography apparatus, an optical metrology inspection tool, or an e-beam inspection tool.

19. The method of claim 15, wherein the component comprises a reticle stage, a wafer stage, a mirror, or a lens element, configured to move into and/or out of one or more positions for photolithography.

20. The method of claim 15, wherein the control input comprise a digital signal indicating one or more selected from: a position, a higher order time derivative of the position, a velocity, or an acceleration of the component over time.

21. The method of claim 15, wherein the control input comprises a digital signal indicating a position and one or more selected from: a higher order time derivative of the position, or an acceleration of the component over time.

22. The method of claim 15, wherein the output comprises one or more selected from: a force, a torque, a current, a voltage, or a charge, used to control movement of the component.

23.-28. (canceled)

29. A non-transitory computer readable medium having instructions therein, the instructions, when executed by a computer system, configured to cause the computer system to implement at least the process of claim 15.

30.-48. (canceled)
